(19) United States
(12) Patent Application Publication
(10) Pub. No.: US 2026/0173330 A1
(43) Pub. Date: Jun. 18, 2026

(54) VEHICULAR ELECTRONIC CONTROL UNIT WITH ENHANCED LIQUID COOLING

(71) Applicant: Magna Electronics Inc., Auburn Hills, MI (US)

(72) Inventors: Deepak Selvaraj, Karnataka (IN); Rajith Jaladihalli Ningappa, Bangalore (IN); Varun S M, Bangalore (IN)

(21) Appl. No.: 19/419,410

(22) Filed: Dec. 15, 2025

Related U.S. Application Data
(60) Provisional application No. 63/735,353, filed on Dec. 18, 2024.

(51) Int. Cl. H05K 7/20; B60R 16/08; H05K 5/00

(52) U.S. Cl. CPC H05K 7/20872; B60R 16/08; H05K 5/0026

(57) ABSTRACT

A vehicular electronic control unit (ECU) includes a housing and a printed circuit board (PCB) accommodated within the housing. Electronic circuitry of the PCB includes an electronic component. When the electronic component is electrically operated, heat generated within the housing is dissipated to a heat dissipating surface that is disposed within a fluid chamber at an exterior side of the housing. Coolant flows within the fluid chamber and heat generated within the housing is dissipated from the heat dissipating surface to the coolant. A nozzle is disposed within the fluid chamber between an inlet port and an outlet port and directs the flow of coolant from the inlet port toward the heat dissipating surface. The coolant flows at a first velocity upstream of the nozzle and flows at a second velocity downstream of the nozzle that is greater than the first velocity.

### CROSS REFERENCE TO RELATED APPLICATION

The present application claims the filing benefits of U.S. provisional application Ser. No. 63/735,353, filed Dec. 18, 2024, which is hereby incorporated herein by reference in its entirety.

### FIELD OF THE INVENTION

The present invention relates generally to a vehicle vision system for a vehicle and, more particularly, to a vehicle vision system that utilizes one or more cameras at a vehicle.

### BACKGROUND OF THE INVENTION

Use of imaging sensors in vehicle imaging systems is common and known. Examples of such known systems are described in U.S. Pat. Nos. 5,949,331; 5,670,935 and/or 5,550,677, which are hereby incorporated herein by reference in their entireties.

### SUMMARY OF THE INVENTION

A vehicular electronic control unit (ECU) includes a housing and a printed circuit board (PCB) accommodated within the housing. The PCB includes electronic circuitry including an electronic component disposed on the PCB. With the vehicular ECU disposed at a vehicle equipped with the vehicular ECU, and when the electronic component is electrically operated, heat is generated within the housing. The heat generated within the housing is dissipated from within the housing to a heat dissipating surface at an exterior side of the housing. The heat dissipating surface is disposed within a fluid chamber at the exterior side of the housing, and, with the vehicular ECU disposed at the equipped vehicle, coolant flows within the fluid chamber along the heat dissipating surface. Heat generated within the housing is dissipated from the heat dissipating surface to the coolant flowing within the fluid chamber. An inlet port is in fluidic connection with the fluid chamber, and with coolant flowing within the fluid chamber, the inlet port directs flow of coolant into the fluid chamber. An outlet port is in fluidic connection with the fluid chamber, and with coolant flowing within the fluid chamber, the outlet port directs the flow of coolant out of the fluid chamber. A nozzle is disposed within the fluid chamber between the inlet port and the outlet port, and with coolant flowing within the fluid chamber, the nozzle directs the flow of coolant from the inlet port toward the heat dissipating surface. The coolant flows at a first velocity or flow rate upstream of the nozzle and flows at a second velocity or flow rate downstream of the nozzle, with the second velocity being greater than the first velocity.

These and other objects, advantages, purposes and features of the present invention will become apparent upon review of the following specification in conjunction with the drawings.

### BRIEF DESCRIPTION OF THE DRAWINGS

FIG. 1 is a perspective view of a vehicle with a vision system;

FIG. 2 includes views of an electronic control unit (ECU) module associated with the vision system;

FIGS. 3 and 4 show example flow rate gradients of coolant flowing within a fluid chamber of the housing portion of the ECU module;

FIG. 5 shows example flow paths of the coolant flowing within the fluid chamber;

FIG. 5A is an enlarged view of area A of FIG. 5; and

FIGS. 6-8 show example heat gradients of the ECU module during electrical operation of at least one heat generating component within the ECU module and with coolant flowing within the fluid chamber.

### DESCRIPTION OF THE PREFERRED EMBODIMENTS

A vehicle vision system and/or driver or driving assist system and/or object detection system and/or alert system operates to capture images exterior of the vehicle and may process the captured image data to display images and to detect objects at or near the vehicle and in the predicted path of the vehicle, such as to assist a driver of the vehicle in maneuvering the vehicle in a rearward direction. The vision system includes an image processor or image processing system that is operable to receive image data from one or more cameras and provide an output to a display device for displaying images representative of the captured image data. Optionally, the vision system may provide display, such as a rearview display or a top down or bird's eye or surround view display or the like.

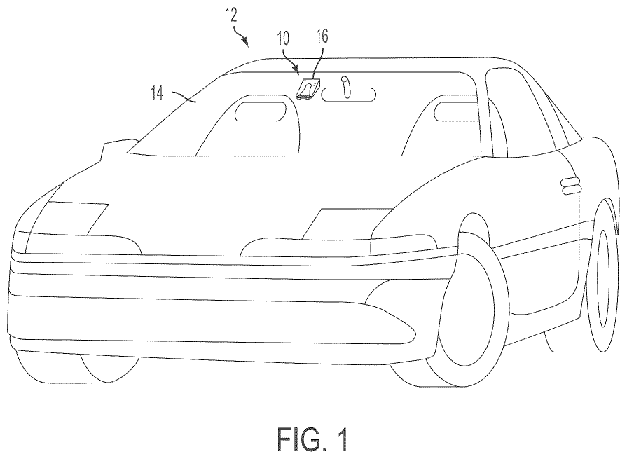

Referring now to the drawings and the illustrative embodiments depicted therein, a vision system 10 for a vehicle 12 includes at least one exterior viewing imaging sensor or camera, such as a forward viewing imaging sensor or camera, which may be disposed at and behind the windshield 14 of the vehicle and viewing forward through the windshield so as to capture image data representative of the scene occurring forward of the vehicle (FIG. 1). Optionally, the system may include multiple exterior viewing imaging sensors or cameras, such as a forward viewing camera at the front of the vehicle, and a sideward/rearward viewing camera at respective sides of the vehicle, and a rearward viewing camera at the rear of the vehicle, which capture images exterior of the vehicle. The camera or cameras each include a lens for focusing images at or onto an imaging array or imaging plane or imager of the camera. The forward viewing camera may be part of a camera module or windshield mounted electronics module (WEM) 16 disposed at the windshield 14 of the vehicle 12 and that views through the windshield and forward of the vehicle, such as for a machine vision system (such as for traffic sign recognition, headlamp control, pedestrian detection, collision avoidance, lane marker detection and/or the like). The vision system 10 includes a control or electronic control unit (ECU) having electronic circuitry and associated software, with the electronic circuitry including a data processor or image processor that is operable to process image data captured by the camera or cameras, whereby the ECU may detect or determine presence of objects or the like and/or the system provide displayed images at a display device for viewing by the driver of the vehicle. The camera module 16 may accommodate the ECU or the ECU may be disposed at any suitable location at the vehicle. The data transfer or signal communication from the camera to the ECU may comprise any suitable data or communication link, such as a vehicle network bus or the like of the equipped vehicle.

Advanced driving assistance systems (ADAS) or vision systems include a significantly increasing number of features and perform an increasing number of functions to both provide additional functionality to consumers and also to meet industry standards and governmental regulations. Additionally, a common or singular or central ECU may process data from various sensors in the vehicle (e.g., exterior viewing camera module, radar sensors, driver/cabin monitoring camera, surround view system cameras, cameras for camera monitoring systems (CMS), and the like) to provide the additional functionality. For example, the ECU module may include one or more printed circuit boards (PCBs) accommodating one or more integrated chips or integrated circuits (ICs) to provide the increased processing. An increased number of features and functions results in a higher demand for processing speed and increased power consumption by ECUs and ADAS modules.

When the ECU provides the additional functionality and increased processing, this may result in greater heat generation at the ECU module. However, requirements for maximum operating ambient temperature of the ECU may require the ECU to operate below a threshold temperature, such as 85 degrees Celsius or less, because operating electronics devices at high temperatures, such as above the threshold temperature, is a challenge. That is, with the growing demand to integrate multiple PCBs and provide multifunctional electronics on one platform, this increases the thermal risks to the ICs and may cause failure.

Thermal solutions to cool the heat generating electrical components and the ECU modules of the vehicle may include natural convection of heat away from the ECU module, forced convection of heat away from the ECU module using fans that direct cooling airflow across heat sinks thermally coupled to the ECU module, and liquid cooling using coolants that draw heat away from the ECU module. Natural convection and forced convection via fan may be limited by the heat carrying capacity and lower heat transfer coefficient of air, and thus may not meet thermal requirements for the ECU module. Liquid cooling, such as with glycol coolant or a mixture of glycol coolant and water (e.g., glycol 40 coolant, glycol 50 coolant, glycol 60 coolant, and the like), may enhance heat transfer away from the ECU module as the coolant has a higher specific heat and heat transfer coefficient. As discussed further below, the ECU module may include a housing or enclosure that is configured to receive liquid coolant and direct liquid coolant along and/or within the housing to dissipate heat from the ECU module to the liquid coolant so that the heated coolant may be directed away from the ECU module to provide cooling to the ECU module.

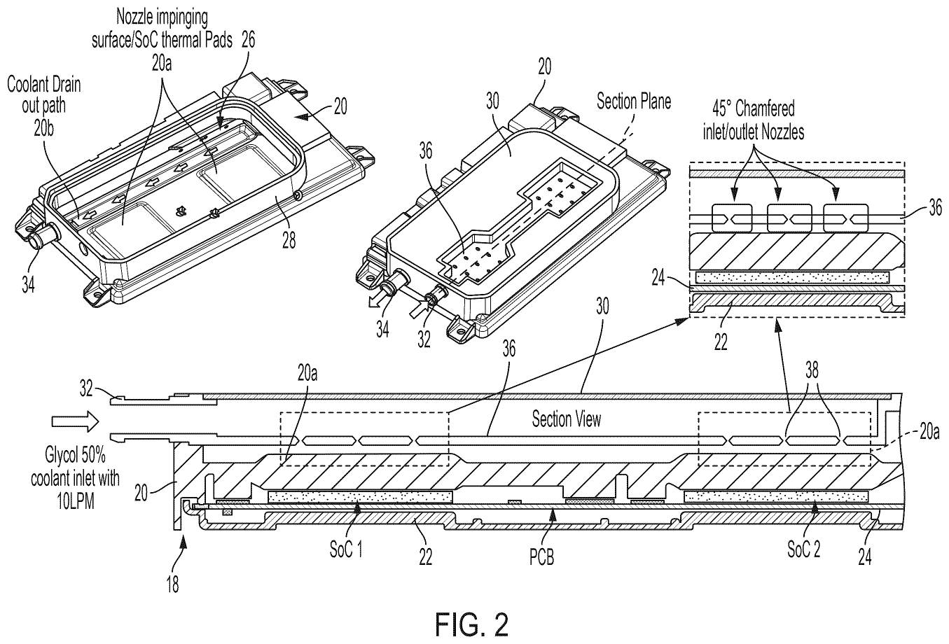

Referring to FIG. 2, an ECU module 18 includes a first or upper housing portion 20, and the upper housing portion 20 may join or mate with a second or lower housing portion 22 to accommodate one or more heat generating electronic components at an interior portion of the ECU housing. For example, a printed circuit board (PCB) 24 may be disposed within the interior portion of the housing and include electronic circuitry that generates heat when electrically operated. In the illustrated example, the PCB 24 accommodates one or more system on chips (SoCs) or ICs at a first side of the PCB 24, and an opposing second side of the PCB 24 may be disposed at or face the lower housing portion 22. The one or more heat generating components thermally interface with an inner side or portion of the upper housing portion 20. For example, the SoCs at the first side of the PCB 24 may engage the inner side of the upper housing portion 20. Thus, when the heat generating components are electrically operated, heat generated within the interior portion of the ECU housing may be at least partially drawn to the upper housing portion 20 to be dissipated away from the ECU module 18.

Optionally, a thermally conductive element or thermal interface material, such as a thermal gel or paste, may be placed between the heat generating component and the upper housing portion 20 to enhance heat dissipation from the heat generating component to the upper housing portion 20. Further, the ECU housing may be formed from any suitable thermally conductive material like a metal alloy, such as an aluminum alloy like aluminum diecast A380, stamped aluminum A6061 and the like, with a range of thermal conductivity to provide an efficient and cost-effective solution.

The upper housing portion 20 includes a liquid jacket or fluid chamber or flow area 26, where coolant may flow into, along, and out of the fluid chamber 26 to dissipate heat away from the upper housing portion 20. The fluid chamber 26 is fluidically sealed or separated from the interior portion of the ECU module 18 and defines an interior portion or area configured to accommodate flow of coolant through the fluid chamber 26. In the illustrated example, the fluid chamber 26 includes outer perimeter walls 28 extending from an outer surface of the upper housing portion 20 and a cover or top plate 30 may extend along and between the outer edges of the perimeter walls 28 to seal the fluid chamber 26. For example, the top plate 30 may meet design for manufacturing (DFM) and friction stir welding (FSW) guidelines. FSW may be used to ensure proper sealing for the fluid chamber 26. The top plate 30 may also be formed from a suitable thermally conductive material like a metal alloy, such as an aluminum alloy like aluminum diecast A380, stamped aluminum A6061 and the like.

Further, the outer surface of the upper housing portion 20 includes one or more impinging surfaces, heat dissipating surfaces or raised portions 20a extending partially into the fluid chamber 26 toward the top plate 30. The impinging surfaces 20a may respectively include a portion of the upper housing portion 20 that is at least partially raised from the remainder of the outer surface of the upper housing portion 20. For example, the impinging surfaces 20a may include a portion of the upper housing portion 20 with a greater thickness than the thickness of the remainder of the upper housing portion 20. The impinging surfaces 20a are spaced from the top plate 30 to allow coolant to flow over and along the impinging surfaces 20a. As discussed further below, the one or more impinging surfaces 20a may be disposed at portions of the upper housing portion 20 corresponding to positions of the heat generating electronic components at the interior portion of the ECU module 18 to encourage thermal transfer from the heat generating components through the upper housing portion 20 and to the coolant via the impinging surfaces 20a.

An inlet port 32 is disposed at the perimeter wall 28 and supplies flow of coolant to the fluid chamber 26, such as from a coolant reservoir and/or pump, and an outlet port 34 is disposed at the perimeter wall 28 spaced apart from the inlet port 32 and directs flow of coolant from the fluid chamber 26, such as back to the reservoir or pump. An intermediate plate or flow guide 36 is disposed between the top plate 30 and the outer surface of the upper housing portion 20 and is configured to direct flow of coolant from the inlet port 32 toward at least the impinging surfaces 20a. Moreover, the outer surface of the upper housing portion 20 may include one or more channels or recesses 20b at least partially recessed from the outer surface of the upper housing portion 20 and configured to direct flow of coolant toward the outlet port 34. For example, the channel 20b may include a substantially linear recess extending parallel to a longitudinal axis of the ECU module 18, adjacent to one or more of the impinging surfaces 20a and aligned with the outlet port 34.

The flow guide 36 may include a lower portion that extends generally parallel to and spaced between the outer surface of the upper housing portion 20 and an inner surface of the top plate 30. Circumferential walls may extend between the lower portion of the flow guide 36 and the inner surface of the top plate 30. Thus, the area or volume or region or portion between the flow guide 36 and the top plate 30 may be separated from other areas or volumes or regions or portions of the fluid chamber 26. The inlet port 32 directs flow of coolant into this separated portion of the fluid chamber 26. Nozzles or openings 38 are formed through the lower portion of the flow guide 36 at positions corresponding to the impinging surfaces 20a beneath the flow guide 36. For example, the flow guide 36 may include a grid or array of individual nozzles 38 spaced from one another and configured to provide coverage for the surface area of the impinging surfaces 20a. The nozzles 38 may be necked or chamfered (such as at 30 degrees, 45 degrees, 60 degrees and the like).

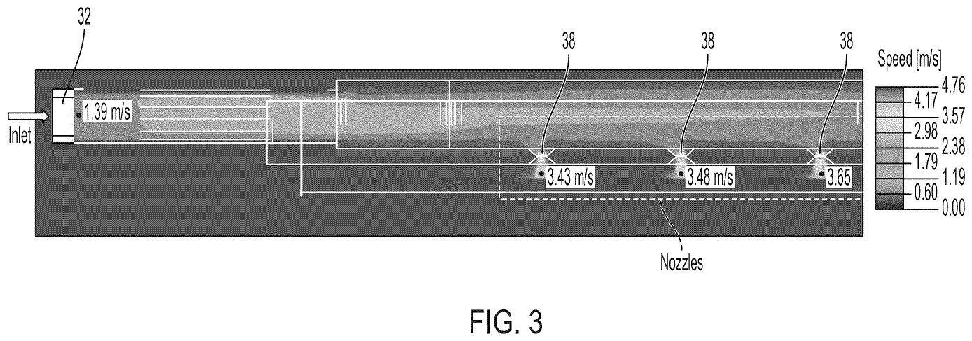

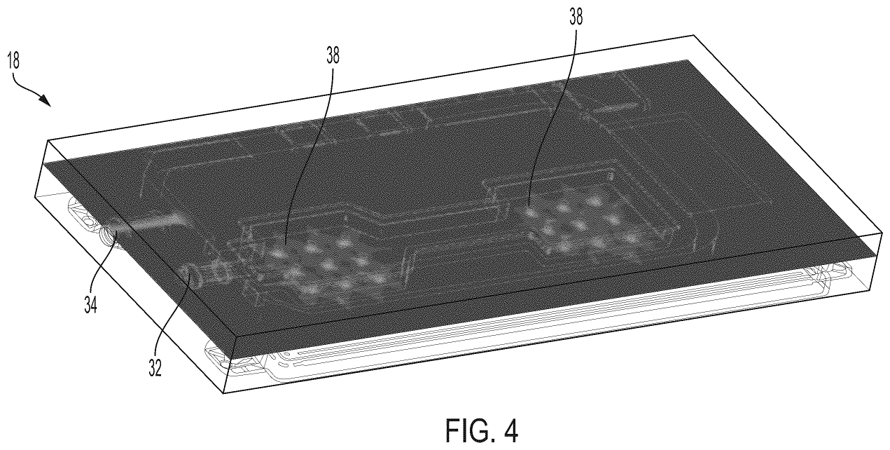

Referring to FIGS. 3 and 4, as coolant flows into the fluid chamber 26 from the inlet port 32, the coolant flows within the separated portion of the fluid chamber 26 and along the flow guide 36. The coolant flows through the nozzles 38 and is directed toward the impinging surfaces 20a of the upper housing 20, with the nozzles 38 configured to increase a velocity or flow rate of the coolant through the nozzles 38, such as by two times or more, three times or more, four times or more and the like. That is, with the coolant flowing into the fluid chamber 26 via the inlet port 32 at a substantially constant flow rate, the coolant may exit the inlet port 32 and enter the fluid chamber 26 at a certain velocity, with the nozzle 38 increasing the velocity of the coolant as the coolant flows toward the impinging surfaces 20a. For example, glycol 50 coolant directed through the inlet port 32 at a temperature of about 65 degrees Celsius and at a rate of about 1.39 meters per second may flow through the nozzles 38 and against the impinging surfaces 20a at a rate of about 3.43 meters per second or more, 3.48 meters per second or more, 3.65 meters per second or more and the like. The flow guide 36 also increases flow rate of the coolant across the impinging surfaces 20a by directing the coolant flow toward the impinging surfaces 20a as the coolant travels between the inlet port 32 and the outlet port 34. As the coolant flows against and along the impinging surfaces 20a, heat is transferred from the upper housing portion 20 and to the coolant. The coolant then flows away from the impinging surfaces 20a, along the drainage channel 20b and out of the fluid chamber 26 through the outlet port 34.

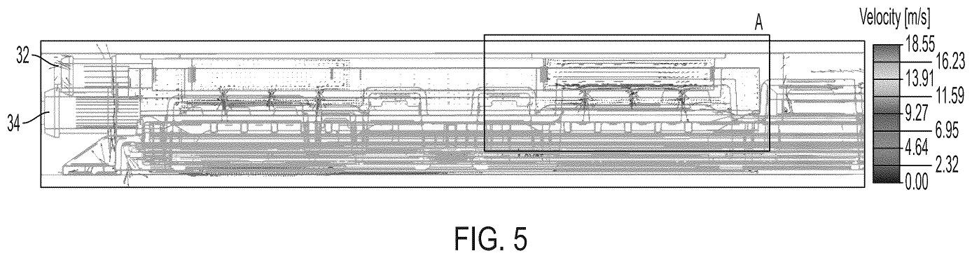

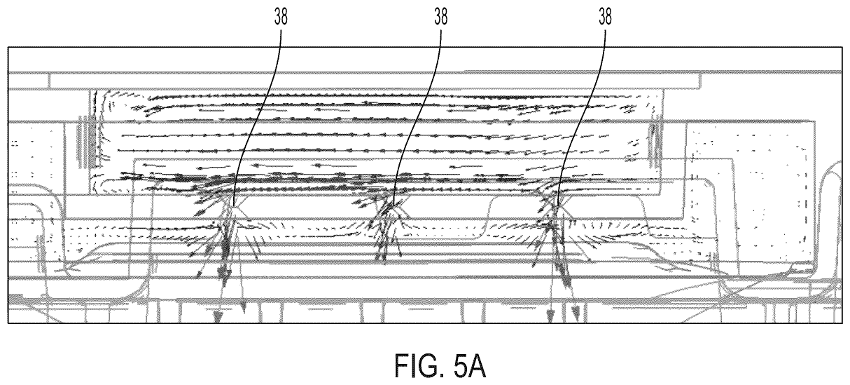

As shown in FIGS. 5 and 5A, the coolant flows along the flow guide 36 and downward through the nozzles 38 toward the impinging surfaces 20a. The nozzles 38 may include a first inward chamfer at an upper portion or surface of the flow guide 36 to increase the flow rate of the coolant into the nozzles 38 and a second outward chamfer at a lower portion or surface of the flow guide 36 to cause the coolant to spray or exit the nozzle 38 at various angles relative to the nozzle 38 and increase the surface area of the impinging surface 20a that is affected by the increased coolant flow rate. The outlet port 34 may be disposed at least partially below or lower than the inlet port 32 to encourage the flow of coolant downward through the nozzles 38 and toward the outlet port 34.

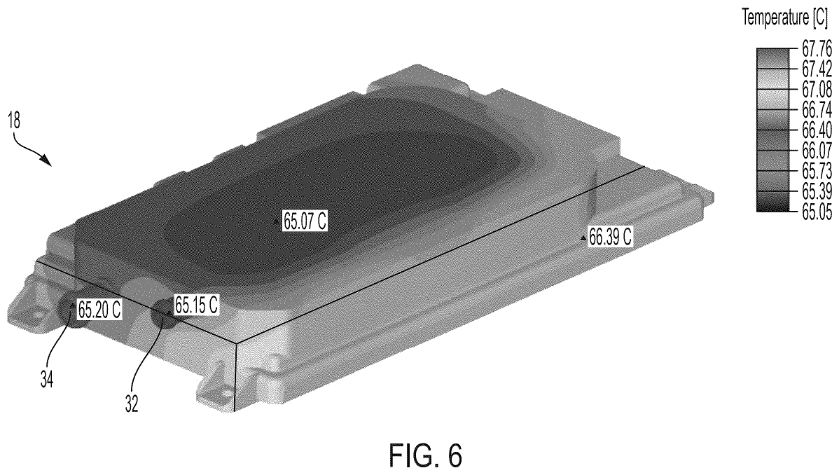

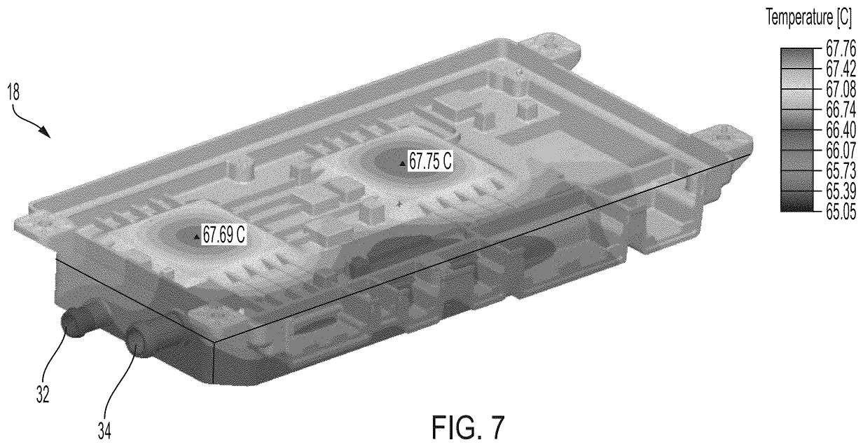

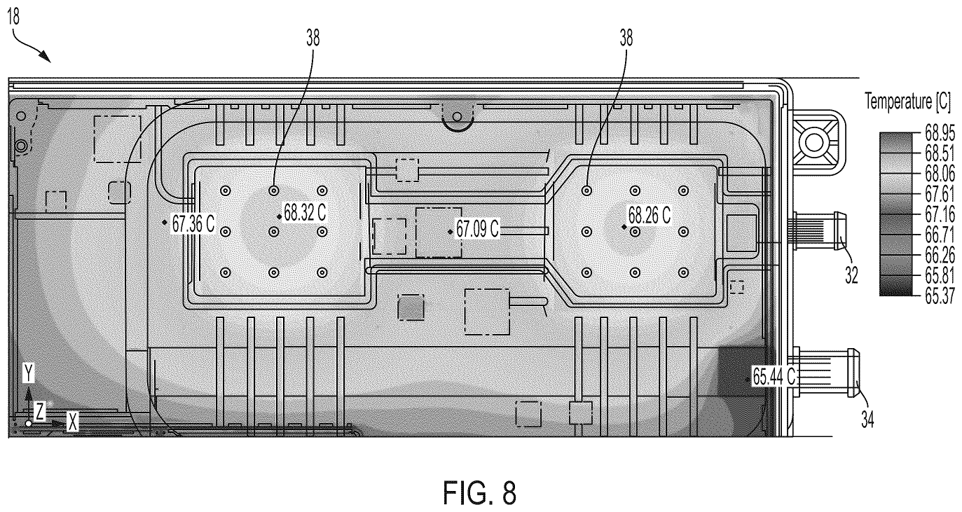

FIGS. 6-8 show example thermal gradients of the ECU module 18 during electrical operation of the heat generating components and during flow of coolant through the fluid chamber 26. As shown, hottest portions of the interior of the ECU module 18 may correspond to positions of the SoCs at the PCB 24 (e.g., FIGS. 7 and 8), such as at about 67.69 degrees Celsius, about 67.75 degrees Celsius, about 68.26 degrees Celsius, about 68.32 degrees Celsius and the like. Meanwhile, coolest portions of the fluid chamber 26 may correspond to the inlet port 32, such as at about 65.15 degrees Celsius, the outlet port 34, such as at about 65.2 degrees Celsius and the flow guide 36, such as at about 65.07 degrees Celsius (e.g., FIG. 6). As coolant flows through the fluid chamber 26, heat is dissipated from within the ECU module 18 through the upper housing portion 20, such as at the impinging surfaces 20a, and drawn away from the ECU module 18 by the coolant directed at and flowing along the upper housing portion 20. By increasing the flow rate and velocity of the coolant at and along the impinging surfaces 20a, thermal transfer from these hottest portions of the ECU module 18 may be increased and the coolant may more effectively and efficiently draw heat away from the ECU module 18.

In other words, the ECU module 18 implements a jet impingement cooling technique in a liquid-cooled ECU to reduce SoC junction temperature by enhancing heat transfer through aggregated velocities of liquid jet flow targeted toward the hot spots caused by high power consumption of the SoCs. Amplifying the velocity of the coolant, such as by three times or more, from the inlet toward targeted surfaces of the upper housing portion 20 enhances the heat transfer at localized spots induced by SoC power consumption. That is, higher velocities of the fluid flow may increase the heat transfer coefficient between the upper housing portion 20 to the coolant, and this can be achieved by design of the nozzles 38 to direct the liquid coolant onto the target impinging surfaces 20a that are in connection with the SoC through thermal gel. Convective heat transfer may be directly proportional to velocity of the fluid flow.

Because the increased flow rate and velocity enhance heat dissipation to the coolant, the ECU module 18 may be configured to receive greater power input and handle greater processing loads. Further, the heat generating components of the ECU module 18 may be positioned in relatively close proximity to one another (e.g., at or near the impinging surfaces 20a) without causing too high a concentration of heat. This may allow for smaller packaging of the ECU module 18 with increased processing capacity.

That is, the ECU module 18 having the fluid chamber 26 integrated with the upper housing portion 20 with nozzles 38 for increasing flow rate and velocity of coolant through the upper housing portion 20 concentrates the high velocity coolant flow toward hot spots of the ECU module 18, which achieves higher thermal effectiveness. SoCs with higher power loads can be effectively cooled and operations performed at elevated ambient temperatures. Higher efficiency ICs/SoCs can be used without changing the sizing of the PCB and mechanical components of the ECU module 18. Thermal fatigue failure that may be induced due to high temperatures may be mitigated.

Benefits include enhancing the heat transfer by increasing the flow velocity from the inlet by three times or more. Better thermal efficiency can be achieved by using this concept. Higher working fluid (coolant) temperatures can be achieved as the working fluid may more effectively draw heat from the upper housing portion 20. Accordingly, larger power input on the module can be achieved at a given ambient temperature. Further, thermal fatigue will be reduced. The design of the housing may be simplified by removing channelized fins and other guide structures, which will minimize material used and cost related to the material. Further, the IC components may be grouped or clustered near to the hot spot hence lesser copper traces required to connect these ICs in the PCB, hence reducing the copper material usage and in turn reduction in PCB manufacturing cost. Moreover, more effectively transferring heat to the coolant allows for use of lower grade and more cost-effective coolant. Operating temperatures of the IC are improved and the lifespan of the IC is improved due to lower thermal expansion of different components and the PCB. Thus, the ECU module provides an effective solution for thermal constraints faced due to higher temperatures on the IC.

Models of the ECU module 18 may be subjected to flow and thermal simulations to extract flow details and temperature data on the IC to quantify the impact of jet impingement on the targeted surfaces. Thus, the configuration of the ECU module 18, such as the position of the nozzles 38, volume of the flow chamber 26, and position of the heat generating components may be adjusted to achieve optimized cooling efficiency. The optimized design may satisfy manufacturing guidelines, with housing material considered to be Aluminum Diecast A380, Stamped Top Cover Aluminum A6061 and the like. Friction stir welding methods may be used to fuse the cover with the housing. Any suitable liquid coolant, such as glycol 50 at 10 liters per minute and at 65 degrees Celsius, may be provided to the inlet port 32.

Characteristics of the ECU module 18 described herein may be suitable for use with a vehicular camera module or other type of vehicular ECU module. In other words, the ECU module may include electronic circuitry for a camera module, ADAS ECU module, body control module, door control module, and the like.

The ECU module may utilize characteristics of the modules described in U.S. U.S. Pat. Nos. 11,997,371 and/or 11,290,622, and/or U.S. Patent Publication Nos. US-2025-0081411; US-2024-0132003 and/or US-2021-0306538, which are all hereby incorporated herein by reference in their entireties.

The ECU module may include an image processor operable to process image data captured by the camera or cameras, such as for detecting objects or other vehicles or pedestrians or the like in the field of view of one or more of the cameras. For example, the image processor may comprise an image processing chip selected from the EYEQ family of image processing chips available from Mobileye Vision Technologies Ltd. of Jerusalem, Israel, and may include object detection software (such as the types described in U.S. Pat. Nos. 7,855,755; 7,720,580 and/or 7,038,577, which are hereby incorporated herein by reference in their entireties), and may analyze image data to detect vehicles and/or other objects. Responsive to such image processing, and when an object or other vehicle is detected, the system may generate an alert to the driver of the vehicle and/or may generate an overlay at the displayed image to highlight or enhance display of the detected object or vehicle, in order to enhance the driver's awareness of the detected object or vehicle or hazardous condition during a driving maneuver of the equipped vehicle.

The vehicle may include any type of sensor or sensors, such as imaging sensors or radar sensors or lidar sensors or ultrasonic sensors or the like. The imaging sensor of the camera may capture image data for image processing and may comprise, for example, a two dimensional array of a plurality of photosensor elements arranged in at least 640 columns and 480 rows (at least a 640×480 imaging array, such as a megapixel imaging array or the like), with a lens focusing images onto the imaging array. The photosensor array may comprise a plurality of photosensor elements arranged in a photosensor array having rows and columns. The imaging array may comprise a CMOS imaging array having at least 300,000 photosensor elements or pixels, preferably at least 500,000 photosensor elements or pixels and more preferably at least one million photosensor elements or at least two million photosensor elements or pixels or at least three million photosensor elements or pixels or at least five million photosensor elements or pixels arranged in rows and columns. The imaging array may be sensitive to near-infrared light. The imaging array may capture color image data, such as via spectral filtering at the array, such as via an RGB (red, green and blue) filter or via a red/red complement filter or such as via an RCC (red, clear, clear) filter or the like. The logic and control circuit of the imaging sensor may function in any known manner, and the image processing and algorithmic processing may comprise any suitable means for processing the images and/or image data.

For example, the vision system and/or processing and/or camera and/or circuitry may utilize aspects described in U.S. Pat. Nos. 9,233,641; 9,146,898; 9,174,574; 9,090,234; 9,077,098; 8,818,042; 8,886,401; 9,077,962; 9,068,390; 9,140,789; 9,092,986; 9,205,776; 8,917,169; 8,694,224; 7,005,974; 5,760,962; 5,877,897; 5,796,094; 5,949,331; 6,222,447; 6,302,545; 6,396,397; 6,498,620; 6,523,964; 6,611,202; 6,201,642; 6,690,268; 6,717,610; 6,757,109; 6,802,617; 6,806,452; 6,822,563; 6,891,563; 6,946,978; 7,859,565; 5,550,677; 5,670,935; 6,636,258; 7,145,519; 7,161,616; 7,230,640; 7,248,283; 7,295,229; 7,301,466; 7,592,928; 7,881,496; 7,720,580; 7,038,577; 6,882,287; 5,929,786 and/or 5,786,772, and/or U.S. Publication Nos. US-2014-0340510; US-2014-0313339; US-2014-0347486; US-2014-0320658; US-2014-0336876; US-2014-0307095; US-2014-0327774; US-2014-0327772; US-2014-0320636; US-2014-0293057; US-2014-0309884; US-2014-0226012; US-2014-0293042; US-2014-0218535; US-2014-0218535; US-2014-0247354; US-2014-0247355; US-2014-0247352; US-2014-0232869; US-2014-0211009; US-2014-0160276; US-2014-0168437; US-2014-0168415; US-2014-0160291; US-2014-0152825; US-2014-0139676; US-2014-0138140; US-2014-0104426; US-2014-0098229; US-2014-0085472; US-2014-0067206; US-2014-0049646; US-2014-0052340; US-2014-0025240; US-2014-0028852; US-2014-005907; US-2013-0314503; US-2013-0298866; US-2013-0222593; US-2013-0300869; US-2013-0278769; US-2013-0258077; US-2013-0258077; US-2013-0242099; US-2013-0215271; US-2013-0141578 and/or US-2013-0002873, which are all hereby incorporated herein by reference in their entireties. The system may communicate with other communication systems via any suitable means, such as by utilizing aspects of the systems described in U.S. Pat. Nos. 10,071,687; 9,900,490; 9,126,525 and/or 9,036,026, which are hereby incorporated herein by reference in their entireties.

Optionally, the camera may comprise a forward viewing camera, such as disposed at a windshield electronics module (WEM) or the like. The forward viewing camera may utilize aspects of the systems described in U.S. Pat. Nos. 9,896,039; 9,871,971; 9,596,387; 9,487,159; 8,256,821; 7,480,149; 6,824,281 and/or 6,690,268, and/or U.S. Publication Nos. US-2020-0039447; US-2015-0327398; US-2015-0015713; US-2014-0160284; US-2014-0226012 and/or US-2009-0295181, which are all hereby incorporated herein by reference in their entireties.

The ECU may be operable to process data for at least one driving assist system of the vehicle. For example, the ECU may be operable to process data (such as image data captured by a forward viewing camera of the vehicle that views forward of the vehicle through the windshield of the vehicle) for at least one selected from the group consisting of (i) a headlamp control system of the vehicle, (ii) a pedestrian detection system of the vehicle, (iii) a traffic sign recognition system of the vehicle, (iv) a collision avoidance system of the vehicle, (v) an emergency braking system of the vehicle, (vi) a lane departure warning system of the vehicle, (vii) a lane keep assist system of the vehicle, (viii) a blind spot monitoring system of the vehicle and (ix) an adaptive cruise control system of the vehicle. Optionally, the ECU may also or otherwise process radar data captured by a radar sensor of the vehicle or other data captured by other sensors of the vehicle (such as other cameras or radar sensors or such as one or more lidar sensors of the vehicle). Optionally, the ECU may process captured data for an autonomous control system of the vehicle that controls steering and/or braking and/or accelerating of the vehicle as the vehicle travels along the road.

Changes and modifications in the specifically described embodiments can be carried out without departing from the principles of the invention, which is intended to be limited only by the scope of the appended claims, as interpreted according to the principles of patent law including the doctrine of equivalents.

1. A vehicular electronic control unit (ECU), the vehicular ECU comprising:
a housing;
a printed circuit board (PCB) comprising electronic circuitry;
wherein the PCB is accommodated within the housing;
wherein the electronic circuitry includes an electronic component disposed on the PCB, and wherein, with the vehicular ECU disposed at a vehicle equipped with the vehicular ECU, and when the electronic component is electrically operated, heat is generated within the housing;
wherein the heat generated within the housing is dissipated from within the housing to a heat dissipating surface at an exterior side of the housing;
wherein the heat dissipating surface is disposed within a fluid chamber at the exterior side of the housing, and wherein, with the vehicular ECU disposed at the equipped vehicle, coolant flows within the fluid chamber along the heat dissipating surface, and wherein the heat generated within the housing is dissipated from the heat dissipating surface to the coolant flowing within the fluid chamber;
wherein an inlet port is in fluidic connection with the fluid chamber, and wherein, with the vehicular ECU disposed at the equipped vehicle, and with coolant flowing within the fluid chamber, the inlet port directs flow of coolant into the fluid chamber;
wherein an outlet port is in fluidic connection with the fluid chamber, and wherein, with the vehicular ECU disposed at the equipped vehicle, and with coolant flowing within the fluid chamber, the outlet port directs the flow of coolant out of the fluid chamber; and
wherein a nozzle is disposed within the fluid chamber between the inlet port and the outlet port, and wherein, with the vehicular ECU disposed at the equipped vehicle, and with coolant flowing within the fluid chamber, the nozzle directs the flow of coolant from the inlet port toward the heat dissipating surface, and wherein the coolant flows at a first velocity upstream of the nozzle and the coolant flows at a second velocity downstream of the nozzle, and wherein the second velocity is greater than the first velocity.

2. The vehicular ECU of claim 1, wherein the fluid chamber comprises a first portion in fluidic connection with the inlet port and a second portion in fluidic connection with the outlet port, and wherein the nozzle is disposed between the first portion of the fluid chamber and the second portion of the fluid chamber.

3. The vehicular ECU of claim 2, wherein a flow guide extends within the fluid chamber and separates the first portion of the fluid chamber from the second portion of the fluid chamber, and wherein the nozzle comprises an opening formed through the flow guide.

4. The vehicular ECU of claim 3, wherein the flow guide is spaced from the exterior side of the housing.

5. The vehicular ECU of claim 3, wherein the nozzle comprises a chamfer.

6. The vehicular ECU of claim 1, wherein the heat dissipating surface is at least partially raised from the exterior side of the housing.

7. The vehicular ECU of claim 1, wherein a channel is disposed at the exterior side of the housing, and wherein the channel, with the vehicular ECU disposed at the equipped vehicle, and with coolant flowing within the fluid chamber, directs the flow of coolant away from the heat dissipating surface and toward the outlet port.

8. The vehicular ECU of claim 1, wherein a thermal interface material is disposed between the electronic component and an interior side of the housing.

9. The vehicular ECU of claim 1, wherein the second velocity is at least two times greater than the first velocity.

10. The vehicular ECU of claim 1, wherein the second velocity is at least three times greater than the first velocity.

11. The vehicular ECU of claim 1, wherein the electronic component comprises a data processor operable to process data captured by at least one sensor of the equipped vehicle.

12. The vehicular ECU of claim 11, wherein the at least one sensor of the equipped vehicle comprises at least one camera of the equipped vehicle.

13. The vehicular ECU of claim 11, wherein the at least one sensor of the equipped vehicle comprises at least one radar sensor of the equipped vehicle.

14. A vehicular electronic control unit (ECU), the vehicular ECU comprising:
a housing;
a printed circuit board (PCB) comprising electronic circuitry;
wherein the PCB is accommodated within the housing;
wherein the electronic circuitry includes an electronic component disposed on the PCB, and wherein, with the vehicular ECU disposed at a vehicle equipped with the vehicular ECU, and when the electronic component is electrically operated, heat is generated within the housing;
wherein the heat generated within the housing is dissipated from within the housing to a heat dissipating surface at an exterior side of the housing;
wherein the heat dissipating surface is disposed within a fluid chamber at the exterior side of the housing, and wherein, with the vehicular ECU disposed at the equipped vehicle, coolant flows within the fluid chamber along the heat dissipating surface, and wherein the heat generated within the housing is dissipated from the heat dissipating surface to the coolant flowing within the fluid chamber;
wherein the fluid chamber comprises a first portion in fluidic connection with an inlet port, and wherein, with the vehicular ECU disposed at the equipped vehicle, and with coolant flowing within the fluid chamber, the inlet port directs flow of coolant into the first portion of the fluid chamber;
wherein the fluid chamber comprises a second portion in fluidic connection with an outlet port, and wherein, with the vehicular ECU disposed at the equipped vehicle, and with coolant flowing within the fluid chamber, the outlet port directs the flow of coolant out of the second portion of the fluid chamber;
wherein a nozzle is disposed within the fluid chamber between the first portion of the fluid chamber and the second portion of the fluid chamber, and wherein, with the vehicular ECU disposed at the equipped vehicle, and with coolant flowing within the fluid chamber, the nozzle directs the flow of coolant from the first portion of the fluid chamber into the second portion of the fluid chamber and toward the heat dissipating surface, and wherein the coolant flows at a first velocity upstream of the nozzle and the coolant flows at a second velocity downstream of the nozzle, and wherein the second velocity is greater than the first velocity; and
wherein a channel is disposed at the exterior side of the housing, and wherein the channel, with the vehicular ECU disposed at the equipped vehicle, and with coolant flowing within the fluid chamber, directs the flow of coolant away from the heat dissipating surface and toward the outlet port.

15. The vehicular ECU of claim 14, wherein a flow guide extends within the fluid chamber and separates the first portion of the fluid chamber from the second portion of the fluid chamber, and wherein the nozzle comprises an opening formed through the flow guide.

16. The vehicular ECU of claim 15, wherein the nozzle comprises a chamfer.

17. The vehicular ECU of claim 14, wherein the electronic component comprises a data processor operable to process data captured by at least one sensor of the equipped vehicle.

18. A vehicular electronic control unit (ECU), the vehicular ECU comprising:
a housing;
a printed circuit board (PCB) comprising electronic circuitry;
wherein the PCB is accommodated within the housing;
wherein the electronic circuitry includes an electronic component disposed on the PCB, and wherein a thermal interface material is disposed between the electronic component and an interior side of the housing, and wherein, with the vehicular ECU disposed at a vehicle equipped with the vehicular ECU, and when the electronic component is electrically operated, heat is generated within the housing;
wherein the heat generated within the housing is dissipated from within the housing to a heat dissipating surface at an exterior side of the housing at least partially through the thermal interface material, and wherein the heat dissipating surface is at least partially raised from the exterior side of the housing;
wherein the heat dissipating surface is disposed within a fluid chamber at the exterior side of the housing, and wherein, with the vehicular ECU disposed at the equipped vehicle, coolant flows within the fluid chamber along the heat dissipating surface, and wherein the heat generated within the housing is dissipated from the heat dissipating surface to the coolant flowing within the fluid chamber;
wherein an inlet port is in fluidic connection with the fluid chamber, and wherein, with the vehicular ECU disposed at the equipped vehicle, and with coolant flowing within the fluid chamber, the inlet port directs flow of coolant into the fluid chamber;
wherein an outlet port is in fluidic connection with the fluid chamber, and wherein, with the vehicular ECU disposed at the equipped vehicle, and with coolant flowing within the fluid chamber, the outlet port directs the flow of coolant out of the fluid chamber; and
wherein a nozzle is disposed within the fluid chamber between the inlet port and the outlet port, and wherein, with the vehicular ECU disposed at the equipped vehicle, and with coolant flowing within the fluid chamber, the nozzle directs the flow of coolant from the inlet port toward the heat dissipating surface, and wherein the coolant flows at a first velocity upstream of the nozzle and the coolant flows at a second velocity downstream of the nozzle, and wherein the second velocity is greater than the first velocity.

19. The vehicular ECU of claim 18, wherein the electronic component comprises a data processor operable to process data captured by at least one sensor of the equipped vehicle.

20. The vehicular ECU of claim 19, wherein the at least one sensor of the equipped vehicle comprises at least one selected from the group consisting of (i) at least one camera of the equipped vehicle and (ii) at least one radar sensor of the equipped vehicle.
